(19) United States
(12) Patent Application Publication
(10) Pub. No.: US 2024/0275339 A1
(43) Pub. Date: Aug. 15, 2024

(54) THERMAL DROOP COMPENSATION IN POWER AMPLIFIERS WITH FIELD-EFFECT TRANSISTORS (FETS)

(71) Applicant: Qorvo US, Inc., Greensboro, NC (US)

(72) Inventors: John Bellantoni, San Jose, CA (US); Michael Kevin O'Neal, Saratoga, CA (US); Michael Simcoe, Pacifica, CA (US)

(21) Appl. No.: 18/519,608

(22) Filed: Nov. 27, 2023

Related U.S. Application Data
(60) Provisional application No. 63/445,047, filed on Feb. 13, 2023.

(51) Int. Cl. H03F 1/30; H03F 3/24

(52) U.S. Cl. CPC H03F 1/301; H03F 3/245; H03F 2200/447; H03F 2200/451

(57) ABSTRACT

Systems and methods for thermal droop compensation in power amplifiers with field effect transistors (FETs) are disclosed. In one aspect, a droop compensation circuit having a heat-sensitive element is embedded in an amplifier in the amplifier chain. The heat-sensitive element tracks changes in temperature for the amplifier and generates a trigger signal for a correction circuit that modifies the amplifier chain to provide thermal droop compensation. Variations contemplate changes to the nature and location of the correction circuit. By compensating for temperature droop in this fashion, rapid pulsing signals that generate rapid pulses of heat may be transmitted across an effectively linear power amplifier chain without having to deal with droop effects. Particular aspects of a FET-based power amplifier may use diodes as a heat-sensitive element.

### PRIORITY APPLICATION

This application claims the benefit of U.S. Provisional Patent Application Ser. No. 63/445,047, filed on Feb. 13, 2023, entitled, “THERMAL DROOP COMPENSATION IN POWER AMPLIFIERS WITH FIELD-EFFECT TRANSISTORS (FETS),” the disclosure of which is hereby incorporated herein by reference in its entirety.

### BACKGROUND

### I. Field of the Disclosure

The technology of the disclosure relates generally to power amplifiers and techniques to compensate for thermal droop thereof.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, the power demands have increased both for the user devices (e.g., smartphones, tablets, laptops) and for the radio nodes that provide wireless connectivity to the user devices. Such increased power demands result in heat being dissipated through the devices, regardless of which end of the wireless connection. As the heat dissipates, operating temperatures may rise, causing changes in operation of power amplifiers (i.e., thermal droop). Correcting for thermal droop provides room for innovation.

### SUMMARY

Aspects disclosed in the detailed description include systems and methods for thermal droop compensation in power amplifiers with field-effect transistors (FETs). In particular, exemplary aspects of the present disclosure contemplate embedding a droop compensation circuit having a heat-sensitive element in an amplifier in an amplifier chain. The heat-sensitive element tracks changes in temperature for the amplifier and generates a trigger signal for a correction circuit that modifies the amplifier chain to provide thermal droop compensation. Variations contemplate changes to the nature and location of the correction circuit. By compensating for temperature droop in this fashion, rapid pulsing signals that generate rapid pulses of heat may be transmitted across an effectively linear power amplifier chain without having to deal with droop effects. Particular aspects of a FET-based power amplifier may use diodes as the heat-sensitive element.

In this regard, in one aspect, an amplifier chain is disclosed. The amplifier chain comprises a power amplifier. The amplifier chain also comprises a heat-sensitive element embedded in the power amplifier responsive to changes in temperature in the power amplifier. The amplifier chain also comprises a reference element coupled to the heat-sensitive element with a node therebetween such that temperature-based changes in the heat-sensitive element perturb the node and draw current thereto, creating a trigger signal. The amplifier chain also comprises a correction circuit coupled to the power amplifier. The correction circuit is configured to receive the trigger signal. The correction circuit is also configured, responsive to receipt of the trigger signal, to provide a thermal droop correction to the power amplifier.

In another aspect, a method of correcting thermal droop in an amplifier chain is disclosed. The method comprises, responsive to heat changes in a heat-sensitive element caused by a proximate power amplifier, perturbing a node between balanced diodes. The method also comprises, responsive to perturbing the node, drawing a current that generates a trigger signal. The method also comprises, responsive to the trigger signal, using a correction circuit to make an adjustment to a radio frequency (RF) path of the proximate power amplifier.

In another aspect, a wireless communication device is disclosed. The wireless communication device includes a transceiver comprising an amplifier chain. The amplifier chain includes a power amplifier and a heat-sensitive element embedded in the power amplifier responsive to changes in temperature in the power amplifier. The amplifier chain also includes a reference element coupled to the heat-sensitive element with a node therebetween such that temperature-based changes in the heat-sensitive element perturb the node and draw current thereto, creating a trigger signal and a correction circuit coupled to the power amplifier. The correction circuit is configured to receive the trigger signal and responsive to receipt of the trigger signal, provide a thermal droop correction to the power amplifier.

### BRIEF DESCRIPTION OF THE DRAWINGS

FIG. 1 is a block diagram of a conventional power amplifier chain having active bias as a first-order approach to temperature-induced droop;

FIG. 2 is a block diagram of a power amplifier chain having a droop circuit attached to an active bias circuit according to exemplary aspects of the present disclosure that provides a signal to a correction circuit for fast corrections to temperature-induced droop;

FIG. 3 is a circuit diagram of an amplifier chain having an active bias circuit embedded in a first power amplifier and a heat-sensitive element in a second power amplifier, where the heat-sensitive element invokes a current flow in the active bias circuit to help correct temperature droop at the first power amplifier according to the present disclosure;

FIG. 4 is a circuit diagram of an amplifier chain having a heat-sensitive element in a second power amplifier, where the heat-sensitive element invokes a current flow in an active bias circuit that biases a gate of the second power amplifier according to the present disclosure;

FIG. 5 is a circuit diagram of an amplifier chain having a heat-sensitive element in a second power amplifier, where the heat-sensitive element invokes a current flow in an active bias circuit of a driver amplifier according to the present disclosure;

FIG. 6 is a circuit diagram of the driver amplifier being used to correct temperature droop for the amplifier chain of FIG. 5;

FIG. 7 is a circuit diagram of an attenuator used in place of the driver amplifier of FIG. 6;

FIG. 8 is a circuit diagram of a single power amplifier having a heat-sensitive element therein, where the heat-sensitive element invokes a current flow in an active bias circuit to help correct temperature droop according to the present disclosure;

FIG. 9 is a circuit diagram of a single power amplifier having a heat-sensitive element therein, where the heat-sensitive element invokes a current flow in an external device similar to FIG. 5;

FIG. 10 provides an amplifier chain similar to FIG. 3 but with an alternate way to generate the thermal signal by not using a negative reference voltage;

FIG. 11 is a flowchart illustrating an exemplary process for providing droop correction to an amplifier chain; and

FIG. 12 is a block diagram of a wireless transceiver system, which may include the droop correction system of FIG. 2 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for thermal droop compensation in power amplifiers with field-effect transistors (FETs). In particular, exemplary aspects of the present disclosure contemplate embedding a droop compensation circuit having a heat-sensitive element in an amplifier in an amplifier chain. The heat-sensitive element tracks changes in temperature for the amplifier and generates a trigger signal for a correction circuit that modifies the amplifier chain to provide thermal droop compensation. Variations contemplate changes to the nature and location of the correction circuit. By compensating for temperature droop in this fashion, rapid pulsing signals that generate rapid pulses of heat may be transmitted across an effectively linear power amplifier chain without having to deal with droop effects. Particular aspects of a FET-based power amplifier may use diodes as the heat-sensitive element.

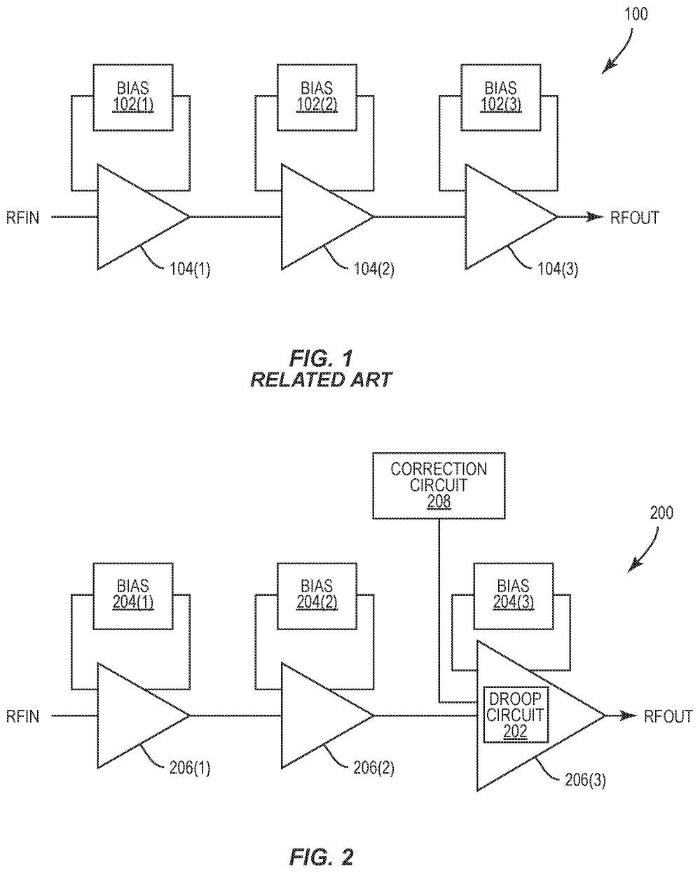

Before addressing particular aspects of the present disclosure, a brief overview of a conventional amplifier chain is provided with reference to FIG. 1, along with an explanation of sources of temperature droop. A discussion of exemplary aspects of the present disclosure that provide an improved droop compensation system begins below with reference to FIG. 2. As a preliminary note of nomenclature, “embedded” as used herein means that the embedded device is positioned immediately adjacent to or within the structure so that a thermal time constant is minimized.

In this regard, FIG. 1 is a block diagram of a conventional power amplifier chain 100 having bias circuits 102(1)-102(3) associated with respective power amplifiers 104(1)-104(3) as a first-order approach to temperature-induced droop. Specifically, a signal to be transmitted is presented at an input node RFIN and amplified by the power amplifiers 104(1)-104(3). The amplified signal is output at an output node RFOUT and may be filtered and transmitted through an antenna (not shown) as is well understood. In some wireless systems, such as wireless local area networks (WiLAN) or cellular base stations, the signal to be transmitted comes in rapid pulses (e.g., typically less than a microsecond). Current amplifier technologies generate heat when a signal is amplified. The rapid pulses likewise generate rapid surges of heat in the circuitry. When transistors within the power amplifiers 104(1)-104(3) are subjected to heat, the transistors may experience a thermal droop, where gain is no longer flat as desired. In particular, for heterojunction bipolar transistors (HBTs), the power amplifiers 104(1)-104(3) may experience a one millivolt drop per degree Celsius (1 mV/° C.) change. Similar droop may also be present for power amplifiers that rely on FETs.

Traditional amplifier chains 100 may use the bias circuits 102(1)-102(3) to provide a fixed current bias signal to the power amplifiers 104(1)-104(3). The rapid pulses of some wireless protocols (e.g., higher-order quadrature amplitude modulation (QAM)) means that there are fast, pulsed temperature fluctuations that may create thermal droop, which is not addressed by these fixed bias circuits.

Exemplary aspects of the present disclosure provide an additional droop circuit that may control a correction circuit to provide additional thermal droop correction for an amplifier chain, as better illustrated in FIG. 2.

In this regard, FIG. 2 is a block diagram of a power amplifier chain 200 having a droop circuit 202. The power amplifier chain 200 may include power amplifiers 206(1)-206(3) each having a respective bias circuit 204(1)-204(3). The droop circuit 202 may be embedded in one of the power amplifiers 206(1)-206(3) (as illustrated, the droop circuit 202 is in the power amplifier 206(3)). As the power amplifier 206(3) heats up from pulsed signals, the droop circuit 202 generates a trigger signal that is sent to a correction circuit 208 to adjust an operating condition in the power amplifier chain 200 to offset the droop caused by the temperature change. The addition of the droop circuit 202 and the correction circuit 208 provides fast corrections to temperature-induced droop.

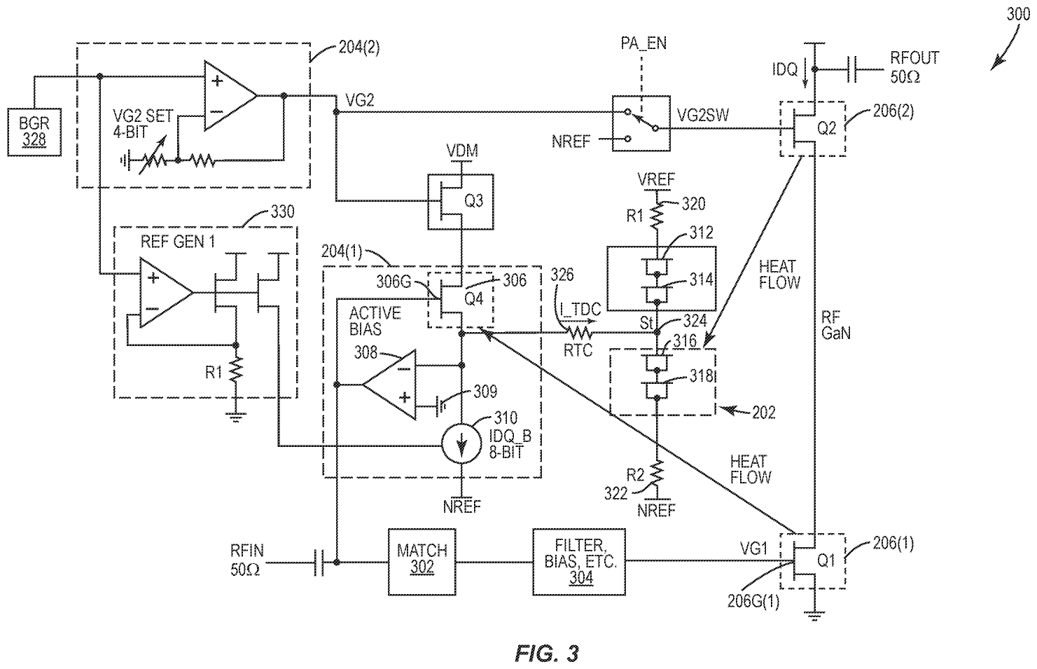

More details about a power amplifier chain 300 that is similar to the power amplifier chain 200, but with only two power amplifiers 206(1) and 206(2), having respective bias circuits 204(1), 204(2), are provided in FIG. 3. While not shown in detail, there may be matching circuitry 302 and other radio frequency (RF) circuitry 304 between RFIN and a gate 206G(1) of the power amplifier 206(1). The bias circuit 204(1) is an active bias circuit and sets a voltage VG1 at the gate 206G(1). Heat from the power amplifier 206(1) flows to an embedded FET 306 (Q4) in the bias circuit 204(1). The embedded FET 306 acts as a current mirror for the power amplifier 206(1). Additionally, the FET 306 is in a current-locked loop in that a negative input of an operational amplifier (op-amp) 308 is coupled to the FET 306, and a positive input is coupled to a ground 309. To keep the input pins equal, an output of the op-amp 308 will float as needed. A current source 310 keeps the current through the FET 306 constant, and thus, voltages at gates 306G and 206G(1) are kept constant. Because the power amplifier 206(1) is approximately twenty times larger than the FET 306, small changes in the FET 306 have a twenty times greater impact at the power amplifier 206(1). The net result of the bias circuit 204(1) is to hold the gain of the power amplifier 206(1) constant as a function of temperature, and this approach is a good first-order solution to temperature droop. As of this writing, the authors of the present disclosure are aware of similar active bias structures in HBT technologies but are unaware of any such active bias structures in FET technologies and specifically unaware of any being used for gallium arsenide nitride (GaN) FETs.

While it is possible that the use of an embedded FET 306 for an active bias circuit is unknown, the present disclosure also provides the droop circuit 202 to assist in providing thermal droop compensation. The droop circuit 202 may be a balanced set of diodes 312, 314, 316, 318. In an exemplary aspect, the diodes 312, 314, 316, 318 are Schottky diodes formed from FETs. In some aspects, the performance of the diodes 312, 314, 316, 318 may be impacted by high-frequency signals. Accordingly, there may be a desire to use frequency-limiting techniques with the diodes 312, 314, 316, 318. One such approach is to use bypass capacitors which short out radio frequency signals. Another approach would be to use long-channel FETs. Diodes 312, 314 are effectively ambient temperature sensors and form a reference element. The diodes 312, 314 are not proximate the rest of the FETS in the amplifier chain 300. The diodes 312, 314 are coupled to a positive supply voltage (VREF) through a resistor 320. The diodes 316, 318 are embedded in the power amplifier 206(2) and are coupled to a negative supply voltage (NREF=−VREF) through a resistor 322. A node 324 between the diodes 314, 316 is, in the absence of a temperature-induced droop, is at zero volts (0 V). When the power amplifier 206(2) heats up, heat flows into the diodes 316, 318, changing the voltage at the node 324 (i.e., the balance at the node 324 is perturbed). When the voltage at node 324 changes, this draws current I_TDC through a resistor 326 coupled to the bias circuit 204(1) and, in particular, changes the current at the input node of the op-amp 308. This change at the input of the op-amp 308 causes a change at the output of the op-amp 308 as it floats to make the inputs equal. This change at the output of the op-amp 308 changes the voltage at the gate 206G(1), effectively compensating for the temperature droop at the power amplifier 206(2).

A bandgap reference (BGR) 328 provides a reference voltage for a reference generator circuit 330 for the current source 310. Additionally, the BGR 328 provides a reference voltage for the bias circuit 204(2). A transistor Q3 may additionally help bias Q2.

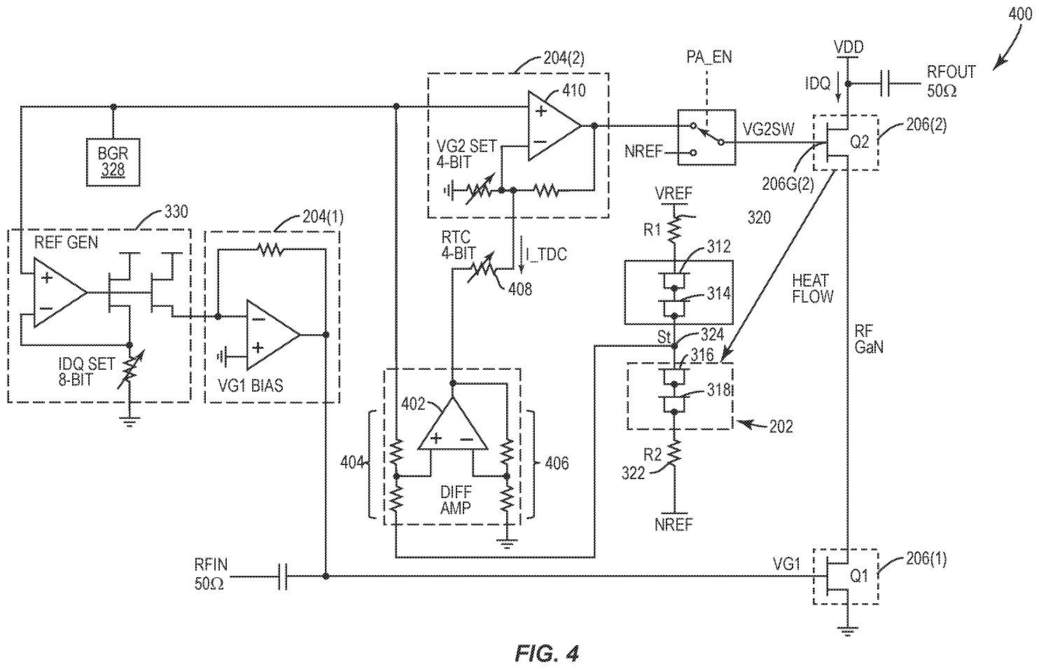

Instead of changing the bias for the power amplifier 206(1), it is also possible to provide droop correction by changing the bias for the power amplifier 206(2), as better illustrated by an amplifier chain 400 in FIG. 4. Many elements remain the same and may not be duplicatively discussed. In the amplifier chain 400, the bias circuit 204(1) is fixed. Heat from the second power amplifier 206(2) raises the temperature of the diodes 316, 318, as discussed above, changing the voltage at the node 324. This pulls current through a differential amplifier 402 with its voltage dividers 404, 406. The differential amplifier 402 floats, pulling current I_TDC through an adjustable resistor 408 (RTC). The adjustable resistor 408 is coupled to the bias circuit 204(2) and pulls the negative input of an op-amp 410 down. The op-amp 410 correspondingly raises the output, which raises the voltage at a gate 206G(2) of the power amplifier 206(2), effectively compensating for thermal droop.

Note that the adjustable resistor 408 also allows an adjustment for how the compensation is set. Note also that the differential amplifier 402 may also be used to step up the voltage from the node 324 (which is designed to be 0 V absent temperature perturbations) to the level of the gate 206G(2) of the power amplifier 206(2).

While it is possible to modify one of the bias circuits 204(1), 204(2), as explained above, it is also possible to provide a trigger signal to a different correction circuit within the amplifier chain. This correction circuit may be a driver amplifier, an attenuator, a modulator, or the like. Several of these options are explored below. Note also that the correction circuit does not need to be on the same die or from the same technology. For example, the correction circuit could be an HBT driver amplifier instead of a FET.

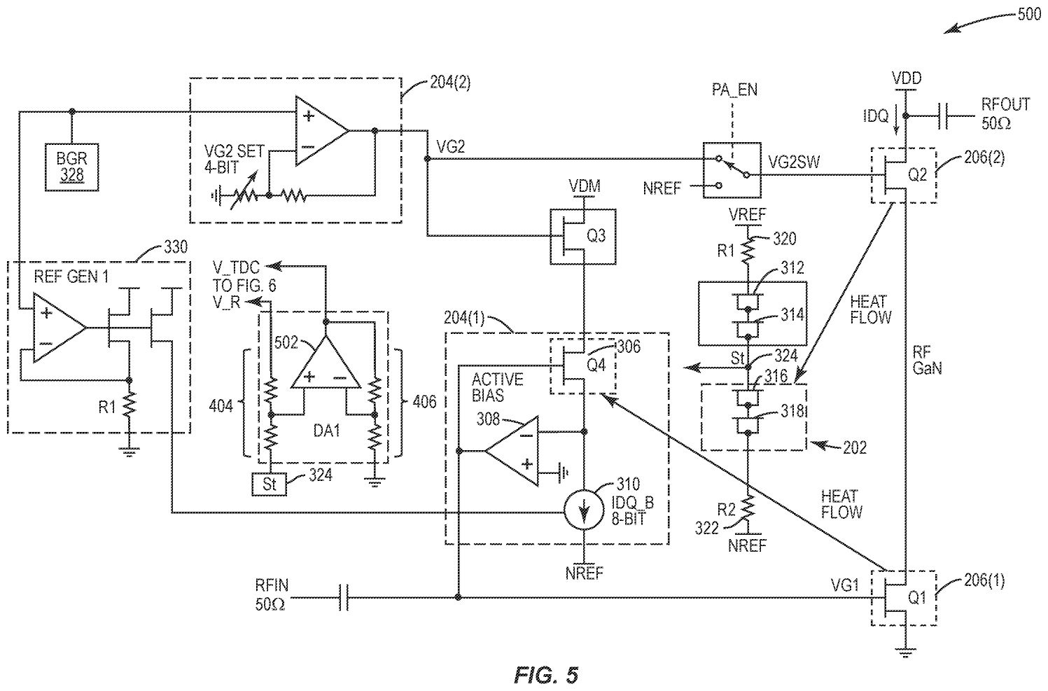

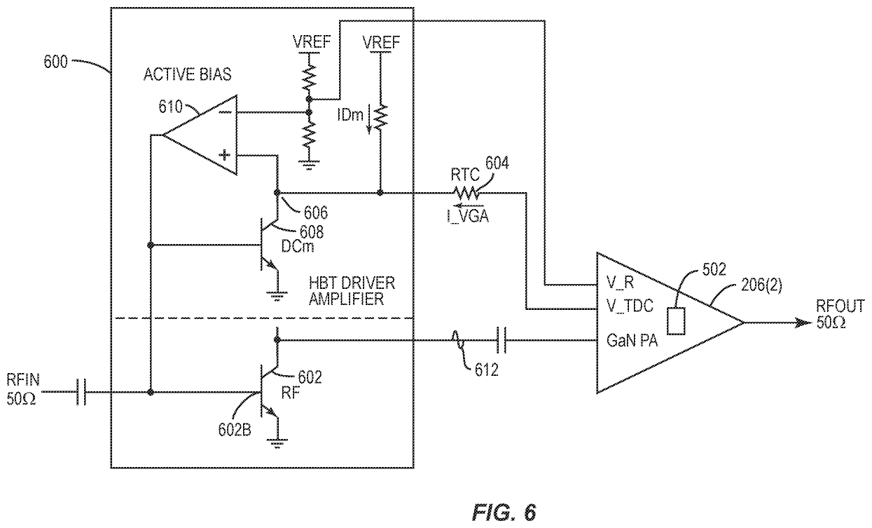

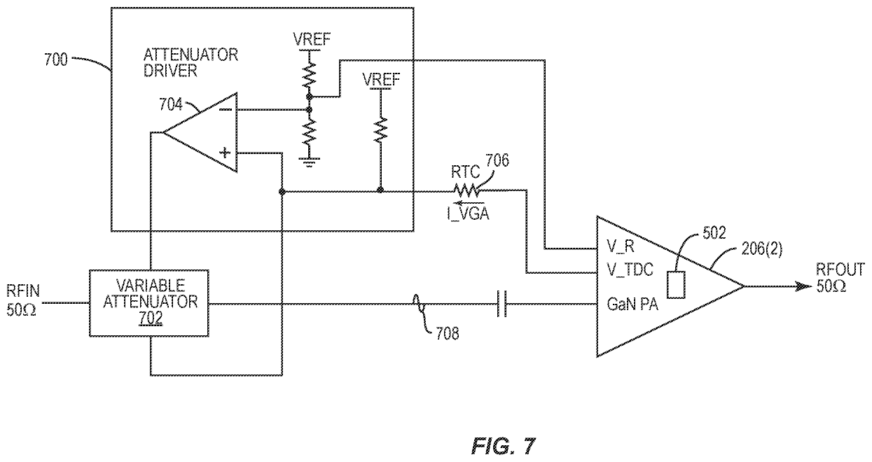

FIG. 5 provides a generic example of a link to a correction circuit with amplifier chain 500. Like the amplifier chain 300 of FIG. 3, the bias circuit 204(1) may be an active bias circuit that provides first-order thermal droop compensation by adjusting current from the FET 306 based on temperature changes in the power amplifier 206(1). Likewise, the bias circuit 204(2) is fixed. Node 324 is still positioned between balanced diodes 312, 314, 316, 318 and coupled to a differential amplifier 502 (similar to the differential amplifier 402 of FIG. 4), but instead of connecting to the bias circuit 204(2), the differential amplifier 502 provides a trigger signal V_TDC, which may be used by a correction circuit such as that shown in FIG. 6 or 7. Note that to reduce clutter, the connection between the node 324 and the differential amplifier 502 is indicated by the label ST.

In this regard, FIG. 6 shows the power amplifier 206(2), and particularly the differential amplifier 502, coupled to a bias circuit 600 for a driver amplifier 602 through a resistor 604 (RTC). The trigger signal is coupled to a node 606 between a transistor 608 and a positive input of an op-amp 610. When the voltage from the differential amplifier 502 changes, the voltage at the node 606 changes, drawing current through the transistor 608. The op-amp 610 floats to keep the input pins equal, changing the bias at a base 602B of the driver amplifier 602. This adjustment at the base 602B means that a signal 612 passed to the power amplifier 206(2) is adjusted to compensate for thermal droop at the power amplifier 206(2).

Instead of a driver amplifier, FIG. 7 shows the trigger signal being sent to an attenuator driver 700 coupled to an attenuator 702 in the input path for the power amplifier 206(2). The attenuator driver 700 includes an op-amp 704 that receives the trigger signal through a resistor 706 (RTC). The op-amp 704 floats to keep the input pins equal, creating a signal that modifies the attenuator 702, thereby modifying a signal 708 passed to the power amplifier 206(2) to compensate for thermal droop at the power amplifier 206(2).

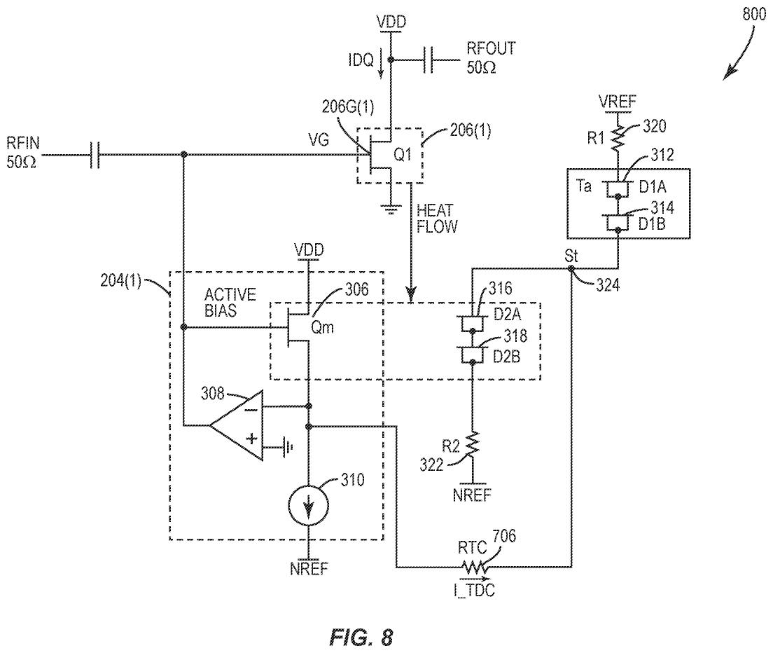

While the above discussion has focused on amplifier chains with multiple power amplifiers, the present disclosure may also work with only a single power amplifier, as illustrated by amplifier chain 800 in FIG. 8. Amplifier chain 800 includes a power amplifier 206(1) with diodes 316, 318 embedded therein. Heat flows from the power amplifier 206(1) to the diodes 316, 318, perturbing the node 324. Likewise, heat flows to a FET 306 in the bias circuit 204(1), making the bias circuit 204(1) an active bias circuit as discussed above. The op-amp 308 floats to change the voltage at the gate 206G(1).

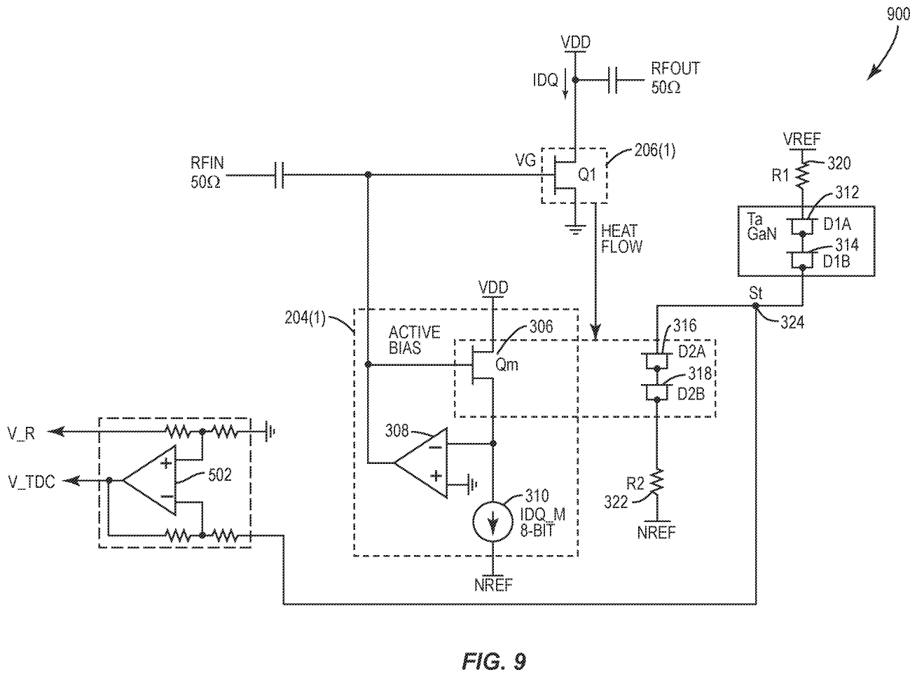

As with other aspects, the single power amplifier 206(1) may also use different correction circuits instead of relying on the bias circuit 204(1) alone. Thus, amplifier chain 900, shown in FIG. 9, couples the node 324 to the differential amplifier 502 that outputs trigger signal V_TDC discussed above. This trigger signal may be coupled to an attenuator, a modulator, a driver amplifier, an HBT driver amplifier, or the like.

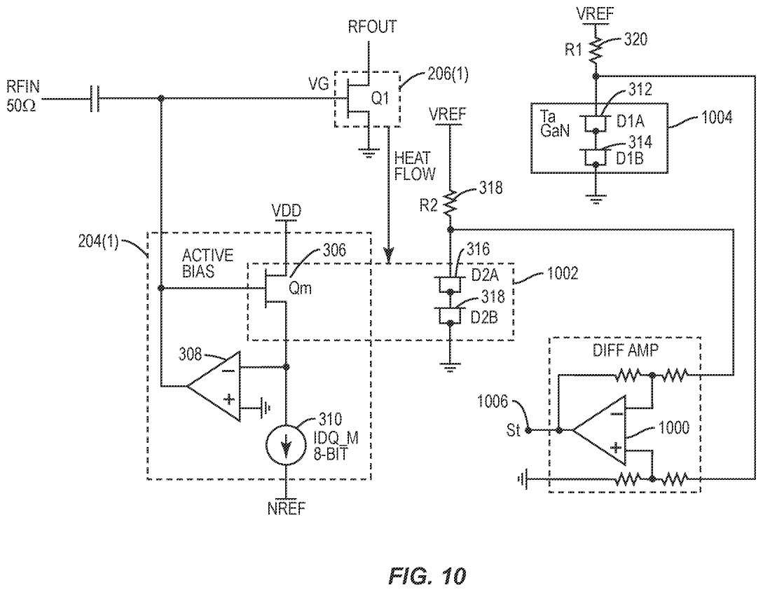

The above aspects contemplate using a positive VREF and a negative NREF to balance the diodes 312, 314, 316, 318. However, this is not strictly required. As shown in FIG. 10, a differential amplifier 1000 may couple diode pairs 1002, 1004 and effectively subtract one from the other to create a node 1006 that is functionally identical to the node 324 discussed in the previous figures.

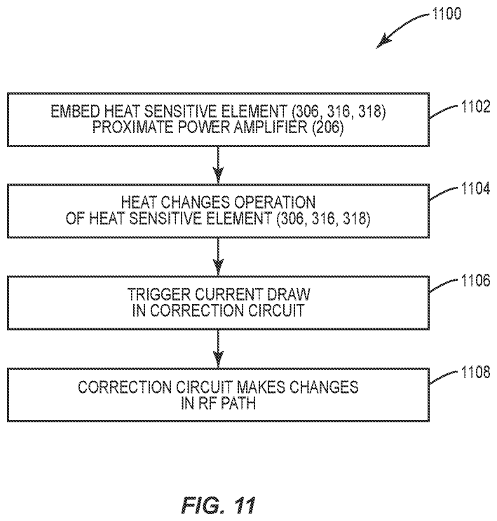

FIG. 11 is a flowchart illustrating an exemplary process 1100 for providing droop correction to an amplifier chain 200 or the like. In particular, the process 1100 begins by embedding a heat-sensitive element (e.g., FET 306, diodes 316, 318) proximate power amplifiers 206 (block 1102). The heat changes operation of the heat-sensitive element (e.g., elements 306, 316, 318) (block 1104), such as by perturbing the node 324 or changing the voltage in the transistor 306. The change in operation triggers a current draw in a correction circuit (block 1106), which may be an active bias circuit, an attenuator, a modulator, a driver amplifier, or the like. The correction circuit makes a change in the RF path to offset thermal drop (block 1108). The correction may be a change to a bias point, a change to the RF input signal, or the like.

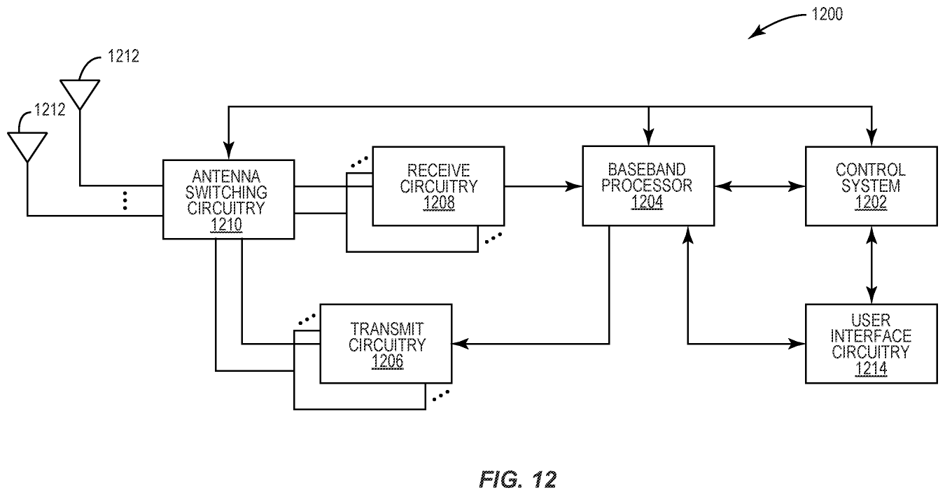

With reference to FIG. 12, the concepts described above may be implemented in various types of user elements 1200, such as mobile terminals, smart watches, tablets, computers, navigation devices, access points, and like wireless communication devices that support wireless communications, such as cellular base stations, wireless local area network (WiLAN), Bluetooth, and near field communications. The user elements 1200 will generally include a control system 1202, a baseband processor 1204, transmit circuitry 1206, receive circuitry 1208, antenna switching circuitry 1210, multiple antennas 1212, and user interface circuitry 1214. In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives RF signals via the antennas 1212 and through the antenna switching circuitry 1210 from one or more base stations. A low noise amplifier and a filter of the receive circuitry 1208 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations, as will be discussed in greater detail below. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally-encoded data into an analog signal, and a modulator modulates the analog signal onto a carrier signal that is at a desired transmit frequency or frequencies. A power amplifier or amplifier chain 200 will amplify the modulated carrier signal to a level appropriate for transmission and deliver the modulated carrier signal to the antennas 1212 through the antenna switching circuitry 1210. The multiple antennas 1212 and the replicated transmit and receive circuitries 1206, 1208 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. An amplifier chain comprising:
a power amplifier;
a heat-sensitive element embedded in the power amplifier responsive to changes in temperature in the power amplifier;
a reference element coupled to the heat-sensitive element with a node therebetween such that temperature-based changes in the heat-sensitive element perturb the node and draw current thereto creating a trigger signal; and
a correction circuit coupled to the power amplifier and configured to:
receive the trigger signal; and
responsive to receipt of the trigger signal, provide a thermal droop correction to the power amplifier.

2. The amplifier chain of claim 1, wherein the heat-sensitive element comprises a pair of diodes.

3. The amplifier chain of claim 2, wherein the pair of diodes comprises a pair of Schottky diodes formed from field-effect transistors (FETs).

4. The amplifier chain of claim 1, wherein the correction circuit comprises an active bias circuit.

5. The amplifier chain of claim 1, wherein the correction circuit comprises an attenuator.

6. The amplifier chain of claim 1, wherein the power amplifier comprises a gallium arsenide (GaN) field-effect transistor (FET).

7. The amplifier chain of claim 6, further comprising an active bias circuit coupled to the power amplifier, wherein the active bias circuit comprises a FET that is thermally coupled to the power amplifier.

8. The amplifier chain of claim 1, wherein the correction circuit comprises a modulator.

9. The amplifier chain of claim 1, wherein the correction circuit comprises a driver amplifier.

10. The amplifier chain of claim 9, wherein the driver amplifier comprises a heterojunction bipolar transistor (HBT).

11. The amplifier chain of claim 1, further comprising a second power amplifier coupled to an active bias circuit and the power amplifier.

12. A method of correcting thermal droop in an amplifier chain, comprising:
responsive to heat changes in a heat-sensitive element caused by a proximate power amplifier, perturbing a node between balanced diodes;
responsive to perturbing the node, drawing a current that generates a trigger signal; and
responsive to the trigger signal, using a correction circuit to make an adjustment to a radio frequency (RF) path of the proximate power amplifier.

13. The method of claim 12, further comprising detecting heat changes in a second power amplifier using a field-effect transistor (FET) embedded in the second power amplifier.

14. The method of claim 12, wherein using the correction circuit to make the adjustment comprises using a driver amplifier to make the adjustment.

15. The method of claim 12, wherein using the correction circuit to make the adjustment comprises using an active bias circuit to make the adjustment.

16. The method of claim 12, wherein using the correction circuit to make the adjustment comprises using an attenuator to make the adjustment.

17. The method of claim 12, wherein using the correction circuit to make the adjustment comprises using a modulator to make the adjustment.

18. A wireless communication device comprising:
a transceiver comprising an amplifier chain comprising:
a power amplifier;
a heat-sensitive element embedded in the power amplifier responsive to changes in temperature in the power amplifier;
a reference element coupled to the heat-sensitive element with a node therebetween such that temperature-based changes in the heat-sensitive element perturb the node and draw current thereto creating a trigger signal; and
a correction circuit coupled to the power amplifier and configured to:
receive the trigger signal; and
responsive to receipt of the trigger signal, provide a thermal droop correction to the power amplifier.
